(19) United States
(12) Patent Application Publication
(10) Pub. No.: US 2024/0364107 A1
(43) Pub. Date: Oct. 31, 2024

(54) MIXED INTEGER PROGRAMMING-BASED LOAD DISAGGREGATION METHOD AND APPARATUS FOR INDUSTRIAL FACILITY

(71) Applicant: TSINGHUA UNIVERSITY, Beijing (CN)

(72) Inventors: Qixin CHEN, Beijing (CN); Chuyi LI, Beijing (CN); Kedi ZHENG, Beijing (CN); Hongye GUO, Beijing (CN)

(21) Appl. No.: 18/759,982

(22) Filed: Jun. 30, 2024

Related U.S. Application Data
(63) Continuation of application No. PCT/CN2022/135019, filed on Nov. 29, 2022.

(30) Foreign Application Priority Data
Mar. 22, 2022 (CN) 202210285953.1

(51) Int. Cl. H02J 3/00

(52) U.S. Cl. CPC H02J 3/00; H02J 2203/20

(57) ABSTRACT

The present disclosure relates to a mixed integer programming-based load disaggregation method and apparatus for an industrial facility. The method includes: obtaining a device asset list of to-be-disaggregated industrial facilities, categorizing the industrial devices into a dynamic load device whose power is continuously adjustable and a steady load device whose power is switched between fixed states; using a predetermined scale of device-level power consumption data as a training set, processing an appropriate load curve of the dynamic load device through digital filtering, and expanding a training dataset of a highly fluctuating pulse portion of the load using time invariance of the highly fluctuating pulse portion of the load; constructing a mixed integer programming model for disaggregation using device information and training data; introducing model modifiers or constraints using physical restrictions such as industrial process dependencies of some devices; and solving a programming problem to obtain a disaggregation result. The method can take load characteristics of both the dynamic load device and the steady load device into consideration simultaneously, in such a manner that non-intrusive load disaggregation having a high degree of accuracy can be performed in industrial scenarios.

### CROSS-REFERENCE TO RELATED APPLICATIONS

This application is a continuation of International Application No. PCT/CN2022/135019 filed on Nov. 29, 2022, which is based on and claims priority to Chinese patent application No. CN202210285953.1 filed on Mar. 22, 2022, the entire contents of which are incorporated herein by reference.

### FIELD

The present disclosure relates to the field of non-intrusive load disaggregation technologies, and more particularly, to a mixed integer programming-based load disaggregation method and apparatus for an industrial facility.

### BACKGROUND

With the rapid development of smart grid and urbanization, the flow of massive information has become an inevitable trend. Power sensors have been widely applied in monitoring load information of various types of electricity consumers. These sensors collect a large amount of load data, which lays the foundation for the development of Internet of Things-based smart grids. In addition, renewable energy is getting more and more attention. The popularization of a large number of renewable energy sources and the gradual phase-out of coal-fired power plants have brought great challenges to the operation of grids. To better promote energy conservation and two-way communication between the supply and demand sides of the grid, feedback on device-level load data from power consumers becomes very important. The feedback can be realized in both intrusive and non-intrusive ways. Typically, intrusive monitoring involves barriers such as sensor mounting, economic cost, and data privacy. In contrast, non-intrusive load monitoring offers consumers the lowest-cost solution with the least amount of effort for the sensor mounting and is therefore considered a more promising option.

Due to huge differences in the scale of power consumption and type of electrical equipment among different power consumers, load disaggregation is usually categorized into three types: load disaggregation for residential facilities, load disaggregation for commercial facilities, and load disaggregation for industrial facilities. Although the application of load disaggregation in commercial and industrial scenarios has a more significant potential profit (the electricity consumption of a single plant may be equivalent to that of hundreds of residences), current research on load disaggregation is mainly focused on residential facilities. Unlike residential scenarios, industrial scenarios involve a large number of dynamic load devices with more complex power usage characteristics, which makes load disaggregation very difficult.

In terms of industrial non-intrusive load monitoring (NILM), load disaggregation in large industrial buildings is first studied in the related art. Power data is collected from a large industrial cold storage. The collected data is compared with typical residential data for analysis. Two benchmark models, a Combinatorial Optimization (CO) algorithm and a Factorial Hidden Markov Model (FHMM), are used to disaggregate the industrial load. Further, improvement measures for targeted training and sub-metering are proposed.

A deep neural network-based disaggregation model is also developed in the related art, which achieves better results than the classical FHMM.

In the related art, active power data and reactive power data in the FHMM are also utilized for industrial load disaggregation, which improves the results to some extent. Currently, to handle industrial scenarios, most of the studies on industrial NILM have only slightly modified the residential NILM model, without designing a suitable model to make use of characteristics of industrial data.

Industrial loads have characteristics such as a large percentage of dynamic loads and pipeline dependency that are rare in residential loads. These characteristics greatly affect the effectiveness of conventional optimization-based models and conventional FHMM-based models. Related studies using deep learning methods have shown that deep learning methods can still achieve satisfactory results in industrial scenarios. In addition, these models are highly dependent on a large amount of training data, but industrial data is often very sensitive, which becomes a major obstacle to model applications.

In the related art, there are two main solution techniques.

(1) k-means clustering technique: this technique can divide datasets into k classes based on distances by iteration given the number k of cluster centers.

(2) Solving technique for a mixed integer programming problem: this technique solves mathematical programming problems in which integers present in independent variables. Generally, the problem is solved based on the branch and bound algorithm. Branch and bound is specifically performed as follows.

All integer constraints on initial mixed integer programming are deleted to obtain slackness of original programming. Generally, the slacked programming is considered to be efficiently solvable. If the solution of the slack problem happens to satisfy all the restrictions of the integer constraints, the solution is optimal for the original mixed integer programming, and the operation terminates. If the solution fails to satisfy all the restrictions of the integer constraints (which is mostly the case), constraints need to be introduced to exclude the solution from a feasible domain. In this case, the original feasible domain is partitioned into two regions, and thus the original problem can be divided into two subproblems to be solved. The two subproblems are called “branches”. The original problem is then replaced by two subproblems with fewer integer variables.

The solution of the above slack problem is the optimal solution in a larger feasible domain. The solution of the original problem must not be better than this solution, and thus the solution of the slack problem is specified as a “lower bound” of the original problem. In a case of branching, the subproblems are continually subdivided, which is likely to result in an optimal solution that satisfies all the constraints of the subproblems. However, the optimal solution is only optimal in the local feasible domain of the original problem, but not necessarily optimal globally. Because of this, the solution is specified as an “upper bound” of the original problem. In the calculation performed on each branching subproblem, if the solution of a subproblem falls outside the currently defined bound, the branch can be deleted without further consideration. Therefore, the branch and bound method is an iterative algorithm that continually updates the upper and lower bounds as subproblems are solved. A numerical solution of the original problem can be obtained when the algorithm satisfies convergence conditions.

Currently, these problems are generally solved using well-established commercial solvers, which generally employ a number of algorithms to optimize the solving speed, such as the cutting-plane algorithm.

### SUMMARY

The present disclosure provides a mixed integer programming-based load disaggregation method and apparatus for an industrial facility, an electronic device, and a storage medium, to solve a problem of a difficulty of conventional load disaggregation techniques in effectively handling complex device load identification in industrial scenarios under restrictions of insufficient industrial load data and difficult data collection. According to the present disclosure, load characteristics of both a dynamic load device and a steady load device can be taken into consideration simultaneously, in such a manner that non-intrusive load disaggregation having a high degree of accuracy can be performed in industrial scenarios.

According to embodiments in a first aspect of the present disclosure, a mixed integer programming-based load disaggregation method for an industrial facility is provided. The method includes: obtaining a device list of to-be-disaggregated industrial devices and a to-be-disaggregated load curve, and obtaining device-level load curves of individual devices based on the device list and the to-be-disaggregated load curve; dividing the to-be-disaggregated industrial devices into a dynamic load device and a steady load device based on power consumption characteristics, performing digital filtering on the device-level load curve of the dynamic load device, and obtaining the processed load curve of the dynamic load device by expanding a highly fluctuating pulse portion of a load using time invariance; constructing a mixed integer programming model based on the processed load curve of the dynamic load device and the load curve of the steady load device, and solving for an optimal value of an optimization variable subsequent to introducing a correction of an industrial process constraint and a device operation restriction into the mixed integer programming model; and reconstructing, based on an optimization problem model, a disaggregation result for a processed composite signal matrix of the dynamic load device, and reconstructing, based on the optimization problem model, a disaggregation result for the steady load device transformed into a power state sequence.

In another exemplary embodiment of the present disclosure, the performing the digital filtering on the device-level load curve of the dynamic load device, and obtaining the processed load curve of the dynamic load device by expanding the highly fluctuating pulse portion of the load using the time invariance includes: removing, by using median filtering, a noise spike from the device-level load curve of the dynamic load device, detecting a large-slope portion of the device-level load curve of the dynamic load device to separate the large-slope portion from the device-level load curve of the dynamic load device, and disaggregating the load of each dynamic device into a smooth basic portion and the highly fluctuating pulse portion; generating column vectors having elements equal to zero in a predetermined time period, connecting the column vectors to a beginning of each to-be-expanded base vector, discarding a sequence of a same length as the column vectors at an end of the to-be-expanded base vector to obtain an expanded pulse lagging by one unit, and obtaining a new base vector by superimposing the expanded pulse on the smooth basic portion; and obtaining the processed load curve of the dynamic load device based on the new base vector and the highly fluctuating pulse portion.

In another exemplary embodiment of the present disclosure, the dividing the to-be-disaggregated industrial devices into the dynamic load device and the steady load device based on the power consumption characteristics includes:
modeling the steady load device using a combinatorial optimization method:

$${\hat{X}}_{n} ( t ) = {\sum }_{k = 1}^{{K}_{n}} {b}_{n , k} ( t ) {x}_{n , k} , ∀ t ∈ T ;$$

$$s . t . :$$

$${b}_{n , k} ( t ) ∈ \{ 0 , 1 \} , ∀ t ∈ T ;$$

$$and$$

$${\sum }_{k = 1}^{{K}_{n}} {b}_{n , k} ( t ) = 1 , ∀ t ∈ T ,$$

where \hat{X}ₙ(t) represents power of device n at a time point t, t represents a time point, T represents a length of a time series for one optimization, n represents a device serial number, b_{n,k}(t) represents a variable for determining a power state of device n, k represents an integer in [1, Kₙ], and Kₙ represents a quantity of states of device n; and
modeling the dynamic load device using a linear combination of the device-level load curves known for the individual devices:

$${\hat{X}}_{n} = {D}_{n} {A}_{n} ;$$

$$and s . t . :$$

$${A}_{n} \geq 0 ,$$

where Ån represents a power time series of device n, Dₙ represents a signal matrix of device n, and Aₙ represents an activation coefficient matrix.

In another exemplary embodiment of the present disclosure, the constructing the mixed integer programming model based on the processed load curve of the dynamic load device and the load curve of the steady load device includes:
connecting signal matrices of individual dynamic load devices as D=[D₁, D₂, . . . , Dₙ], and expressing a load model of the steady load device in a form of a matrix:

$${\hat{X}}_{n} ( t ) = [ \begin{matrix}{b}_{n , 1} ( t ) & {b}_{n , 2} ( t ) & … & {b}_{n , {K}_{n}} ( t )\end{matrix} ] [ \begin{matrix}{x}_{n , 1} \\ {x}_{n , 2} \\ ⋮ \\ {x}_{n , {K}_{n}}\end{matrix} ] , ∀ t ∈ T ;$$

summing dimensions of a same base vector in the signal matrices to obtain:

$${\hat{X}}_{n} = [ \begin{matrix}{\hat{X}}_{n} ( 1 ) \\ {\hat{X}}_{n} ( 2 ) \\ ⋮ \\ {\hat{X}}_{n} ( m )\end{matrix} ] = [ \begin{matrix}{b}_{n , 1} ( 1 ) & {b}_{n , 2} ( 1 ) & ⋯ & {b}_{n , {K}_{n}} ( 1 ) \\ {b}_{n , 1} ( 2 ) & {b}_{n , 2} ( 2 ) & ⋯ & {b}_{n , {K}_{n}} ( 2 ) \\ ⋮ & ⋮ & ⋱ & ⋮ \\ {b}_{n , 1} ( m ) & {b}_{n , 2} ( m ) & ⋯ & {b}_{n , {K}_{n}} ( m )\end{matrix} ] [ \begin{matrix}{x}_{n , 1} \\ {x}_{n , 2} \\ ⋮ \\ {x}_{n , {K}_{n}}\end{matrix} ] = {B}_{n} {X}_{n} ; and$$

constructing the mixed integer programming model:

$${min}_{A , {B}_{n}} {‖ X - D A - {\sum }_{n = 1}^{N} {B}_{n} {X}_{n} ‖}_{F}^{2} + β {‖ U - QA ‖}_{F}^{2}$$

$$s . t . :$$

$$A \geq 0 ,$$

where X represents a load curve read out by a master smart meter of a user, β represents a regular term coefficient, U represents a column vector composed of 1, Q represents a signal grouping matrix, A represents an activation coefficient matrix, N represents a quantity of steady load devices, Xₙ represents a power state matrix, Bₙ represents a state selection matrix, and m represents a length of a time series intercepted for one optimization.

In another exemplary embodiment of the present disclosure, the introducing the correction of the industrial process constraint and the device operation restriction into the mixed integer programming model includes:
setting the industrial process constraint as:

γ∥RA∥_{F}²; and
restricting a maximum duration for the steady load device and a minimum duration for the steady load device,
wherein the maximum duration W_{n,k} is constrained using a set of linear inequalities:

$${\sum }_{i = t}^{t + {W}_{n , k} - 1} {b}_{n , k} ( i ) \leq {W}_{n , k} - 1 ;$$

$$and$$

$$∀ t ∈ \{ 1 , 2 , … , m - {W}_{n , k} + 1 \} ;$$

and wherein the minimum duration w_{n,k} is constrained using a set of linear inequalities:

$${\sum }_{i = t}^{t + {w}_{n , k} - 1} {b}_{n , k} ( i ) \geq {w}_{n , k} ( {b}_{n , k} ( t ) - {b}_{n , k} ( t - 1 ) ) ; and$$

$$∀ t ∈ \{ 2 , 3 , … , m - {w}_{n , k} + 1 \} ,$$

where γ represents a regular term coefficient, and R represents a process restriction matrix.

According to embodiments in a second aspect of the present disclosure, a mixed integer programming-based load disaggregation apparatus for an industrial facility is provided. The apparatus includes: an obtaining module configured to obtain a device list of to-be-disaggregated industrial devices and a to-be-disaggregated load curve, and obtain device-level load curves of individual devices based on the device list and the to-be-disaggregated load curve; a processing module configured to: divide the to-be-disaggregated industrial devices into a dynamic load device and a steady load device based on power consumption characteristics, perform digital filtering on the device-level load curve of the dynamic load device, and obtain the processed load curve of the dynamic load device by expanding a highly fluctuating pulse portion of a load using time invariance; a first calculation module configured to construct a mixed integer programming model based on the processed load curve of the dynamic load device and the load curve of the steady load device, and solve for an optimal value of an optimization variable subsequent to introducing a correction of an industrial process constraint and a device operation restriction into the mixed integer programming model; and a second calculation module configured to reconstruct, based on an optimization problem model, a disaggregation result for a processed composite signal matrix of the dynamic load device, and reconstruct, based on the optimization problem model, a disaggregation result for the steady load device transformed into a power state sequence.

In another exemplary embodiment of the present disclosure, the processing module is specifically configured to: remove, by using median filtering, a noise spike from the device-level load curve of the dynamic load device, detect a large-slope portion of the device-level load curve of the dynamic load device to separate the large-slope portion from the device-level load curve of the dynamic load device, and disaggregate the load of each dynamic device into a smooth basic portion and the highly fluctuating pulse portion; generate column vectors having elements equal to zero in a predetermined time period, connect the column vectors to a beginning of each to-be-expanded base vector, discard a sequence of a same length as the column vectors at an end of the to-be-expanded base vector to obtain an expanded pulse lagging by one unit, and obtain a new base vector by superimposing the expanded pulse on the smooth basic portion; and obtain the processed load curve of the dynamic load device based on the new base vector and the highly fluctuating pulse portion.

In another exemplary embodiment of the present disclosure, the processing module is configured to:
model the steady load device using a combinatorial optimization method:

$${\hat{X}}_{n} ( t ) = {\sum }_{k = 1}^{{K}_{n}} {b}_{n , k} ( t ) {x}_{n , k} , ∀ t ∈ T ;$$

$$s . t : {b}_{n , k} ( t ) ∈ \{ 0 , 1 \} , ∀ t ∈ T ; and$$

$${\sum }_{k = 1}^{{K}_{n}} {b}_{n , k} ( t ) = 1 , ∀ t ∈ T ,$$

where \hat{X}ₙ(t) represents power of device n at a time point t, t represents a time point, T represents a length of a time series for one optimization, n represents a device serial number, b_{n,k} (t) represents a variable for determining a power state of device n, k represents an integer in [1, Kₙ], and Kₙ represents a quantity of states of device n; and
model the dynamic load device using a linear combination of the device-level load curves known for the individual devices:

$${\hat{X}}_{n} = {D}_{n} {A}_{n} ; and$$

$$s . t . : {A}_{n} \geq 0 ,$$

where \hat{X}ₙ represents a power time series of device n, Dₙ represents a signal matrix of device n, and Aₙ represents an activation coefficient matrix.

In another exemplary embodiment of the present disclosure, the first calculation module is further configured to:
connect signal matrices of individual dynamic load devices as D=[D₁, D₂, . . . , Dₙ], and express a load model of the steady load device in a form of a matrix:

$${\hat{X}}_{n} ( t ) = [ {b}_{n , 1} ( t ) {b}_{n , 2} ( t ) ⋯ {b}_{n , {K}_{n}} ( t ) ] [ \begin{matrix}{x}_{n , 1} \\ {x}_{n , 2} \\ ⋮ \\ {x}_{n , {K}_{n}}\end{matrix} ] , ∀ t ∈ T ;$$

sum dimensions of a same base vector in the signal matrices to obtain:

$${\hat{X}}_{n} = [ \begin{matrix}{\hat{X}}_{n} ( 1 ) \\ {\hat{X}}_{n} ( 2 ) \\ ⋮ \\ {\hat{X}}_{n} ( m )\end{matrix} ] = [ \begin{matrix}{b}_{n , 1} ( 1 ) & {b}_{n , 2} ( 1 ) & … & {b}_{n , {K}_{n}} ( 1 ) \\ {b}_{n , 1} ( 2 ) & {b}_{n , 2} ( 2 ) & … & {b}_{n , {K}_{n}} ( 2 ) \\ ⋮ & ⋮ & ⋱ & ⋮ \\ {b}_{n , 1} ( m ) & {b}_{n , 2} ( m ) & ⋯ & {b}_{n , {K}_{n}} ( m )\end{matrix} ] [ \begin{matrix}{x}_{n , 1} \\ {x}_{n , 2} \\ ⋮ \\ {x}_{n , {K}_{n}}\end{matrix} ] = {B}_{n} {X}_{n} ;$$

and
construct the mixed integer programming model:

$${min}_{A , {B}_{n}} {‖ X - DA - {\sum }_{n = 1}^{N} {B}_{n} {X}_{n} ‖}_{F}^{2} + β {‖ U - QA ‖}_{F}^{2}$$

$$s . t . : A \geq 0 ,$$

where X represents a load curve read out by a master smart meter of a user, β represents a regular term coefficient, U represents a column vector composed of 1, Q represents a signal grouping matrix, A represents an activation coefficient matrix, N represents a quantity of steady load devices, Xₙ represents a power state matrix, Bₙ represents a state selection matrix, and m represents a length of a time series intercepted for one optimization.

In another exemplary embodiment of the present disclosure, the first calculation module is further configured to:
set the industrial process constraint as:

γ∥RA∥_{F}²; and
restrict a maximum duration for the steady load device and a minimum duration for the steady load device,
wherein the maximum duration Wnk is constrained using a set of linear inequalities:

$${\sum }_{i = t}^{t + {W}_{n , k} - 1} {b}_{n , k} ( i ) \leq {W}_{n , k} - 1 ; and$$

$$∀ t ∈ \{ 1 , 2 , … , m - {W}_{n , k} + 1 \} ;$$

and wherein the minimum duration w_{n,k} is constrained using a set of linear inequalities:

$${\sum }_{i = t}^{t + {w}_{n , k} - 1} {b}_{n , k} ( i ) \geq {w}_{n , k} ( {b}_{n , k} ( t ) - {b}_{n , k} ( t - 1 ) ) ; and$$

$$∀ t ∈ \{ 2 , 3 , … , m - {w}_{n , k} + 1 \} ,$$

where γ represents a regular term coefficient, and R represents a process restriction matrix.

According to embodiments in a third aspect of the present disclosure, an electronic device is provided. The electronic device includes: a memory; a processor; and a computer program stored in the memory and executable on the processor. The processor is configured to, when executing the computer program, implement the method according to any of the above embodiments.

According to embodiments in a fourth aspect of the present disclosure, a computer-readable storage medium is provided. The computer-readable storage medium stores a computer program. The computer program is configured to, when executed by a processor, implement the method according to any of the above embodiments.

As a result, by obtaining a device asset list of to-be-disaggregated industrial facilities, the industrial devices are categorized into the dynamic load device whose power is continuously adjustable and the steady load device whose power is switched between fixed states. A predetermined scale of device-level power consumption data is used as a training set. An appropriate load curve of the dynamic load device is processed through the digital filtering. A training dataset of a highly fluctuating pulse portion of the load is expanded using the time invariance of the highly fluctuating pulse portion of the load. The mixed integer programming model for disaggregation is constructed using the device information and training data. Model modifiers or constraints are introduced using physical restrictions such as industrial process dependencies of some devices. The programming problem is solved to obtain the disaggregation result. Therefore, the problem of the difficulty of conventional load disaggregation techniques in effectively handling the complex device load identification in industrial scenarios under restrictions of insufficient industrial load data and difficult data collection can be solved. According to the present disclosure, the load characteristics of both the dynamic load device and the steady load device can be taken into consideration simultaneously, in such a manner that the non-intrusive load disaggregation having a high degree of accuracy can be performed in industrial scenarios.

Additional aspects and advantages of the present disclosure will be provided at least in part in the following description, or will become apparent at least in part from the following description, or can be learned from practicing of the present disclosure.

### BRIEF DESCRIPTION OF THE DRAWINGS

The above and/or additional aspects and advantages of the present disclosure will become more apparent and more understandable from the following description of embodiments taken in conjunction with the accompanying drawings.

FIG. 1 is a flowchart of a mixed integer programming-based load disaggregation method for an industrial facility according to an embodiment of the present disclosure.

FIG. 2 is a flowchart of a mixed integer programming-based load disaggregation method for an industrial facility according to an embodiment of the present disclosure.

FIG. 3 is a block diagram showing a mixed integer programming-based load disaggregation apparatus for an industrial facility according to an embodiment of the present disclosure.

FIG. 4 is a schematic diagram of an electronic device according to an embodiment of the present disclosure.

### DETAILED DESCRIPTION

Embodiments of the present disclosure will be described in detail below with reference to examples thereof as illustrated in the accompanying drawings, throughout which same or similar elements, or elements having same or similar functions, are denoted by same or similar reference numerals. The embodiments described below with reference to the drawings are illustrative only, and are intended to explain, rather than limit, the present disclosure.

A mixed integer programming-based load disaggregation method and apparatus for an industrial facility, an electronic device, and a storage medium according to the embodiments of the present disclosure are described below with reference to the accompanying drawings. Regarding the problem of the difficulty of conventional load disaggregation techniques in effectively handling complex device load identification in industrial scenarios under restrictions of insufficient industrial load data and difficult data collection, the present disclosure provides the mixed integer programming-based load disaggregation method for the industrial facility. With the method, by obtaining a device asset list of to-be-disaggregated industrial facilities, the industrial devices are categorized into the dynamic load device whose power is continuously adjustable and the steady load device whose power is switched between fixed states. A predetermined scale of device-level power consumption data is used as a training set. An appropriate load curve of the dynamic load device is processed through the digital filtering. A training dataset of a highly fluctuating pulse portion of the load is expanded using the time invariance of the highly fluctuating pulse portion of the load. The mixed integer programming model for disaggregation is constructed using the device information and training data. Model modifiers or constraints are introduced using physical restrictions such as industrial process dependencies of some devices. The programming problem is solved to obtain the disaggregation result. Therefore, the problem of the difficulty of conventional load disaggregation techniques in effectively handling the complex device load identification in industrial scenarios under restrictions of insufficient industrial load data and difficult data collection can be solved. According to the present disclosure, the load characteristics of both the dynamic load device and the steady load device can be taken into consideration simultaneously, in such a manner that the non-intrusive load disaggregation having a high degree of accuracy can be performed in industrial scenarios.

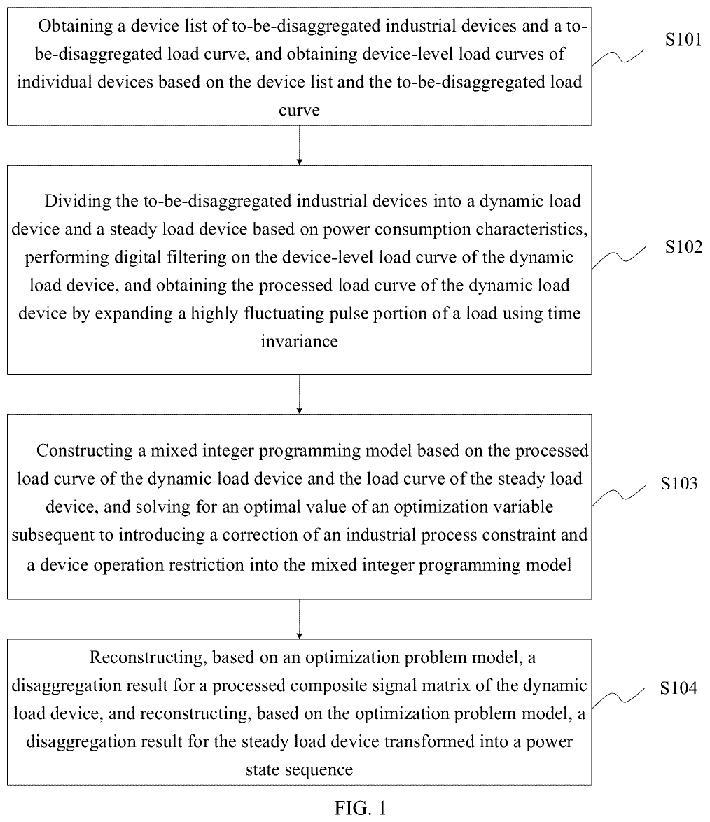

In an exemplary embodiment of the present disclosure, FIG. 1 is a flowchart illustrating a mixed integer programming-based load disaggregation method for an industrial facility according to an embodiment of the present disclosure.

As illustrated in FIG. 1, the mixed integer programming-based load disaggregation method for the industrial facility includes the following operations at blocks.

At block S101, a device list of to-be-disaggregated industrial devices and a to-be-disaggregated load curve are obtained, and device-level load curves of individual devices are obtained based on the device list and the to-be-disaggregated load curve.

A sequence of power readings recorded by a user's low-voltage circuit smart meter in a day is defined as a “total load curve” and recorded as a column vector. A sequence of power readings collected by an individually mounted sensor of an electric device in a day is defined as the “device-level load curve” and recorded as a column vector of a same dimension.

In an exemplary embodiment of the present disclosure, a device asset list of to-be-disaggregated industrial facilities is obtained. The to-be-disaggregated load curve is obtained from smart meters of the to-be-disaggregated industrial facilities. The device-level load curves of individual devices are obtained from a device manufacturer or a device load database.

At block S102, the to-be-disaggregated industrial devices are divided into a dynamic load device and a steady load device based on power consumption characteristics, digital filtering is performed on the device-level load curve of the dynamic load device, and the processed load curve of the dynamic load device is obtained by expanding a highly fluctuating pulse portion of a load using time invariance.

In some embodiments, the dividing the to-be-disaggregated industrial devices into the dynamic load device and the steady load device based on the power consumption characteristics includes:
modeling the steady load device using a combinatorial optimization method:

$${\hat{X}}_{n} ( t ) = {\sum }_{k = 1}^{{K}_{n}} {b}_{n , k} ( t ) {x}_{n , k} , ∀ t ∈ T ;$$

$$s . t : {b}_{n , k} ( t ) ∈ \{ 0 , 1 \} , ∀ t ∈ T ; and$$

$${\sum }_{k = 1}^{{K}_{n}} {b}_{n , k} ( t ) = 1 , ∀ t ∈ T ,$$

where \hat{X}ₙ(t) represents power of device n at a time point t, t represents a time point, T represents a length of a time series for one optimization, n represents a device serial number, b_{n,k} (t) represents a variable for determining a power state of device n, k represents an integer in [1, Kₙ], and Kₙ represents a quantity of states of device n; and
modeling the dynamic load device using a linear combination of the device-level load curves known for the individual devices:

$${\hat{X}}_{n} = {D}_{n} {A}_{n} ; and$$

$$s . t . : {A}_{n} \geq 0 ,$$

where \hat{X}ₙ represents a power time series of device n, Dₙ represents a signal matrix of device n, each column vector of which is the known device-level load curve of the device and is called a base vector; and Aₙ represents an activation coefficient matrix, i.e., a coefficient for a linear combination of the base vectors. Generally, elements of A are required to be non-negative.

In some embodiments, the performing the digital filtering on the device-level load curve of the dynamic load device, and obtaining the processed load curve of the dynamic load device by expanding the highly fluctuating pulse portion of the load using the time invariance includes: removing, by using median filtering, a noise spike from the device-level load curve of the dynamic load device, detecting a large-slope portion of the device-level load curve of the dynamic load device to separate the large-slope portion from the device-level load curve of the dynamic load device, and disaggregating the load of each dynamic device into a smooth basic portion and the highly fluctuating pulse portion; generating column vectors having elements equal to zero in a predetermined time period, connecting the column vectors to a beginning of each to-be-expanded base vector, discarding a sequence of a same length as the column vectors at an end of the to-be-expanded base vector to obtain an expanded pulse lagging by one unit, and obtaining a new base vector by superimposing the expanded pulse on the smooth basic portion; and obtaining the processed load curve of the dynamic load device based on the new base vector and the highly fluctuating pulse portion.

In an exemplary embodiment of the present disclosure, industrial devices are divided based on respective power consumption characteristics during operation into the dynamic load device and the steady load device. The dynamic load device generally contains a variable speed motor. A load curve of the dynamic load device varies in a continuous range. A load curve of the steady load device switches between a series of fixed power states. The two types of devices are modeled in different ways. For the device-level load curve of the dynamic load device, a curve vector corresponding to an appropriate device is processed using the digital filtering. A new vector in line with the reality is constructed using the time invariance of the highly fluctuating pulse portion of the load, to expand the training set. For the device-level load curve of the dynamic load device, the digital filtering is performed. During the digital filtering, the noise peak is removed by using the median filtering, and then the large-slope portion of the curve is detected and separated from the curve. In addition, a limiter is added to assist in pulse identification. Finally, the load of each device is disaggregated into the smooth basic portion and the highly fluctuating pulse portion. The pulse portion is expanded using the time invariance. A fixed length of time is determined, and column vectors having elements, corresponding to that length of time, equal to zero are generated. The column vectors are then connected to the beginning of each to-be-expanded base vector. The sequence of the same length as the column vectors at the end of the base vector is discarded to obtain the expanded pulse lagging by one unit. A new base vector for the device is obtained by superimposing the expanded pulse on the basic portion.

At block S103, a mixed integer programming model is constructed based on the processed load curve of the dynamic load device and the load curve of the steady load device, and an optimal value of an optimization variable is solved for subsequent to introducing a correction of an industrial process constraint and a device operation restriction into the mixed integer programming model.

In some embodiments, the constructing the mixed integer programming model based on the processed load curve of the dynamic load device and the load curve of the steady load device further includes:
connecting signal matrices of individual dynamic load devices as D=[D₁, D₂, . . . , Dₙ], and expressing a load model of the steady load device in a form of a matrix:

$${\hat{X}}_{n} ( t ) = [ {b}_{n , 1} ( t ) {b}_{n , 2} ( t ) ⋯ {b}_{n , {K}_{n}} ( t ) ] [ \begin{matrix}{x}_{n , 1} \\ {x}_{n , 2} \\ ⋮ \\ {x}_{n , {K}_{n}}\end{matrix} ] , ∀ t ∈ T ;$$

summing dimensions of a same base vector in the signal matrices to obtain:

$${\hat{X}}_{n} = [ \begin{matrix}{\hat{X}}_{n} ( 1 ) \\ {\hat{X}}_{n} ( 2 ) \\ ⋮ \\ {\hat{X}}_{n} ( m )\end{matrix} ] = [ \begin{matrix}{b}_{n , 1} ( 1 ) & {b}_{n , 2} ( 1 ) & … & {b}_{n , {K}_{n}} ( 1 ) \\ {b}_{n , 1} ( 2 ) & {b}_{n , 2} ( 2 ) & … & {b}_{n , {K}_{n}} ( 2 ) \\ ⋮ & ⋮ & ⋱ & ⋮ \\ {b}_{n , 1} ( m ) & {b}_{n , 2} ( m ) & ⋯ & {b}_{n , {K}_{n}} ( m )\end{matrix} ] [ \begin{matrix}{x}_{n , 1} \\ {x}_{n , 2} \\ ⋮ \\ {x}_{n , {K}_{n}}\end{matrix} ] = {B}_{n} {X}_{n} ; and$$

constructing the mixed integer programming model:

$${min}_{A , {B}_{n}} {‖ X - DA - {\sum }_{n = 1}^{N} {B}_{n} {X}_{n} ‖}_{F}^{2} + β {‖ U - QA ‖}_{F}^{2}$$

$$s . t . : A \geq 0 ,$$

where X represents a load curve read out by a master smart meter of a user and is the to-be-disaggregated load, and the second term is a regular term for grouping of base vectors, β represents a regular term coefficient, U represents a column vector composed of 1, Q represents a signal grouping matrix, in which each diagonal block of Q is 1, a dimension of Q corresponds to a quantity of base vectors grouped, and elements in other regions are 0, A represents an activation coefficient matrix, N represents a quantity of steady load devices, Xₙ represents a power state matrix, Bₙ represents a state selection matrix, and m represents a length of a time series intercepted for one optimization.

In some embodiments, the introducing the correction of the industrial process constraint and the device operation restriction into the mixed integer programming model includes:
setting the industrial process constraint as adding an additional penalty term to an optimization objective function (mixed integer programming model):

γ∥RA∥_{F}²;
restricting a maximum duration for the steady load device and a minimum duration for the steady load device, wherein the maximum duration W_{n,k} is constrained using a set of linear inequalities:

$${\sum }_{i = t}^{t + {W}_{n , k} - 1} {b}_{n , k} ( i ) \leq {W}_{n , k} - 1 ; and$$

$$∀ t ∈ \{ 1 , 2 , … , m - {W}_{n , k} + 1 \} ;$$

and wherein the minimum duration w_{n,k} is constrained using a set of linear inequalities:

$${\sum }_{i = t}^{t + {w}_{n , k} - 1} {b}_{n , k} ( i ) \geq {w}_{n , k} ( {b}_{n , k} ( t ) - {b}_{n , k} ( t - 1 ) ) ; and$$

$$∀ t ∈ \{ 2 , 3 , … , m - {w}_{n , k} + 1 \} ,$$

where γ represents a regular term coefficient, and R represents a process restriction matrix. R consists of a series of unit matrices connected to each other. Chunks corresponding to pairs of devices that have a process relationship with each other are a positive unit matrix and a negative unit matrix, respectively.

At block S104, a disaggregation result is reconstructed, based on an optimization problem model, for a processed composite signal matrix of the dynamic load device, and a disaggregation result is reconstructed, based on the optimization problem model, for the steady load device transformed into a power state sequence.

In an exemplary embodiment of the present disclosure, the disaggregation result is obtained by solving the above optimization problem using mixed integer programming solving technology to obtain A, Bₙ, reconstructing the dynamic load device load through the load model DA, and reconstructing the steady load device load through BₙXₙ.

As a result, by combining advantages of the classical combinatorial optimization model in dealing with the steady load device and advantages of the matrix disaggregation model in dealing with the dynamic load device, the present disclosure achieves uniform solving in one optimization programming problem. The present disclosure is more suitable for complex industrial scenarios in which different types of loads are mixed, as compared to other algorithms based on a probabilistic model and based on an optimization model. In addition, the problem of data dependency is also taken into consideration in the present disclosure. Compared with widely used deep learning models, the present disclosure can achieve the same level of disaggregation effect as general deep learning models while using less training data. Further, the present disclosure can make full use of available data in practical industrial application scenarios to obtain a more accurate load disaggregation result, and is therefore of great significance and has a broad application prospect.

To provide those skilled in the art with a further understanding of the mixed integer programming-based load disaggregation method for the industrial facility, description is made below in conjunction with specific embodiments.

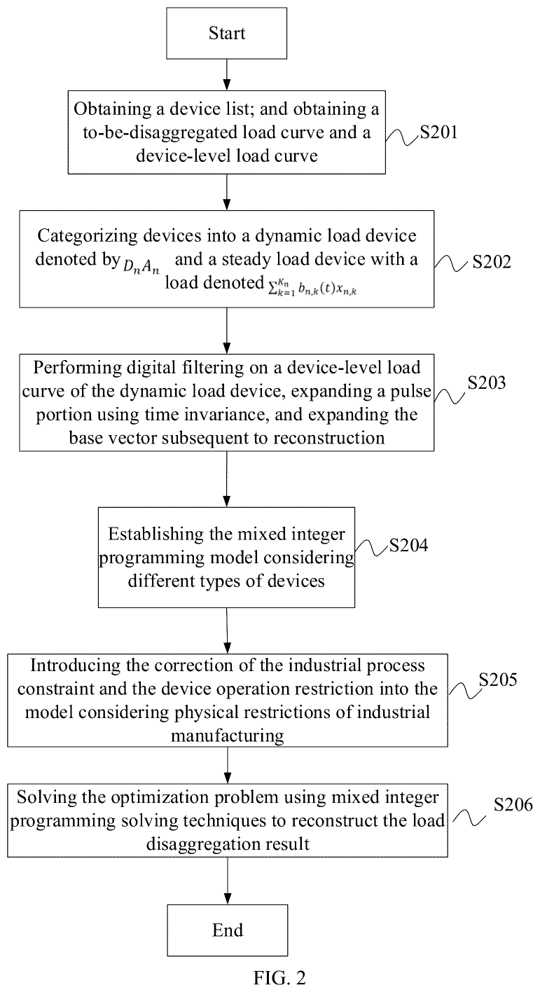

FIG. 2 is a flowchart of the mixed integer programming-based load disaggregation method for the industrial facility.

At block S201, a device list is obtained; and a to-be-disaggregated load curve and a device-level load curve are obtained.

At block S202, devices are categorized into a dynamic load device denoted by DₙAₙ and a steady load device with a load denoted by Σₖ₌₁^{K}^{ₙ}b_{n,k}(t)x_{n,k}.

At block S203, digital filtering is performed on a device-level load curve of the dynamic load device, a pulse portion is expanded using time invariance, and the base vector is expanded subsequent to reconstruction.

At block S204, the mixed integer programming model is established considering different types of devices.

At block S205, the correction of the industrial process constraint and the device operation restriction are introduced into the model considering physical restrictions of industrial manufacturing.

At block S206, the optimization problem is solved using mixed programming solving techniques to reconstruct the load disaggregation result.

With the mixed integer programming-based load disaggregation method for the industrial facility according to the embodiments of the present disclosure, by obtaining the device asset list of to-be-disaggregated industrial facilities, the industrial devices are categorized into the dynamic load device whose power is continuously adjustable and the steady load device whose power is switched between fixed states. A predetermined scale of device-level power consumption data is used as a training set. An appropriate load curve of the dynamic load device is processed through the digital filtering. The training dataset of the highly fluctuating pulse portion of the load is expanded using the time invariance of the highly fluctuating pulse portion of the load. The mixed integer programming model for disaggregation is constructed using the device information and training data. Model modifiers or constraints are introduced using physical restrictions such as industrial process dependencies of some devices. The programming problem is solved to obtain the disaggregation result. Therefore, the problem of the difficulty of conventional load disaggregation techniques in effectively handling the complex device load identification in industrial scenarios under restrictions of insufficient industrial load data and difficult data collection can be solved. According to the present disclosure, the load characteristics of both the dynamic load device and the steady load device can be taken into consideration simultaneously, in such a manner that the non-intrusive load disaggregation having a high degree of accuracy can be performed in industrial scenarios.

A mixed integer programming-based load disaggregation apparatus for an industrial facility according to the embodiments of the present disclosure is described below with reference to the accompanying drawings.

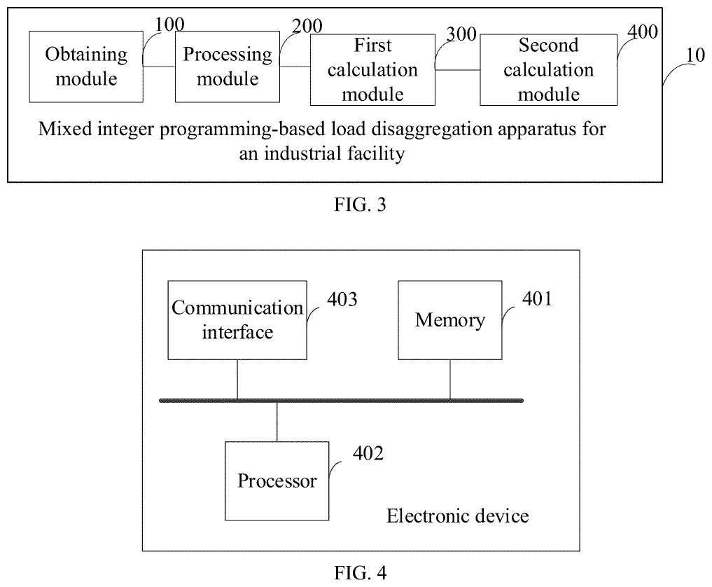

FIG. 3 is a block diagram showing a mixed integer programming-based load disaggregation apparatus for an industrial facility according to an embodiment of the present disclosure.

As illustrated in FIG. 3, a mixed integer programming-based load disaggregation apparatus 10 for an industrial facility includes an obtaining module 100, a processing module 200, a first calculation module 300, and a second calculation module 400.

The obtaining module 100 is configured to obtain a device list of to-be-disaggregated industrial devices and a to-be-disaggregated load curve, and obtain device-level load curves of individual devices based on the device list and the to-be-disaggregated load curve.

The processing module 200 is configured to: divide the to-be-disaggregated industrial devices into a dynamic load device and a steady load device based on power consumption characteristics, perform digital filtering on the device-level load curve of the dynamic load device, and obtain the processed load curve of the dynamic load device by expanding a highly fluctuating pulse portion of a load using time invariance.

The first calculation module 300 is configured to construct a mixed integer programming model based on the processed load curve of the dynamic load device and the load curve of the steady load device, and solve for an optimal value of an optimization variable subsequent to introducing a correction of an industrial process constraint and a device operation restriction into the mixed integer programming model.

The second calculation module 400 is configured to reconstruct, based on an optimization problem model, a disaggregation result for a processed composite signal matrix of the dynamic load device, and reconstruct, based on the optimization problem model, a disaggregation result for the steady load device transformed into a power state sequence.

In some embodiments, the processing module 200 is specifically configured to: remove, by using median filtering, a noise spike from the device-level load curve of the dynamic load device, detect a large-slope portion of the device-level load curve of the dynamic load device to separate the large-slope portion from the device-level load curve of the dynamic load device, and disaggregate the load of each dynamic device into a smooth basic portion and the highly fluctuating pulse portion; generate column vectors having elements equal to zero in a predetermined time period, connect the column vectors to a beginning of each to-be-expanded base vector, discard a sequence of a same length as the column vectors at an end of the to-be-expanded base vector to obtain an expanded pulse lagging by one unit, and obtain a new base vector by superimposing the expanded pulse on the smooth basic portion; and obtain the processed load curve of the dynamic load device based on the new base vector and the highly fluctuating pulse portion.

In some embodiments, the processing module 200 is configured to: model the steady load device using a combinatorial optimization method:

$${\hat{X}}_{n} ( t ) = {\sum }_{k = 1}^{{K}_{n}} {b}_{n , k} ( t ) {x}_{n , k} , ∀ t ∈ T ; \\ s . t . : {b}_{n , k} ( t ) ∈ \{ 0 , 1 \} , ∀ t ∈ T ; and \\ {\sum }_{k = 1}^{{K}_{n}} {b}_{n , k} ( t ) = 1 , ∀ t ∈ T ,$$

where \hat{X}ₙ (t) represents power of device n at a time point t, t represents a time point, T represents a length of a time series for one optimization, n represents a device serial number, b_{n,k}(t) represents a variable for determining a power state of device n, k represents an integer in [1, Kₙ], and Kₙ represents a quantity of states of device n; and
model the dynamic load device using a linear combination of the device-level load curves known for the individual devices:

$${\hat{X}}_{n} = {D}_{n} {A}_{n} ; and \\ s . t . : {A}_{n} \geq 0 ,$$

where \hat{X}ₙ represents a power time series of device n, Dₙ represents a signal matrix of device n, and Aₙ represents an activation coefficient matrix.

In another exemplary embodiment of the present disclosure, the first calculation module 300 is further configured to:
connect signal matrices of individual dynamic load devices as D=[D₁, D₂, . . . , Dₙ], and express a load model of the steady load device in a form of a matrix:

$${\hat{X}}_{n} ( t ) = [ \begin{matrix}{b}_{n , 1} ( t ) & {b}_{n , 2} ( t ) & … & {b}_{n , {K}_{n}} ( t )\end{matrix} ] [ \begin{matrix}{x}_{n , 1} \\ {x}_{n , 2} \\ ⋮ \\ {x}_{n , {K}_{n}}\end{matrix} ] , ∀ t ∈ T ;$$

sum dimensions of a same base vector in the signal matrices to obtain:

$${\hat{X}}_{n} = [ \begin{matrix}{\hat{X}}_{n} ( 1 ) \\ {\hat{X}}_{n} ( 2 ) \\ ⋮ \\ {\hat{X}}_{n} ( m )\end{matrix} ] = [ \begin{matrix}{b}_{n , 1} ( 1 ) & {b}_{n , 2} ( 1 ) & … & {b}_{n , {K}_{n}} ( 1 ) \\ {b}_{n , 1} ( 2 ) & {b}_{n , 2} ( 2 ) & … & {b}_{n , {K}_{n}} ( 2 ) \\ ⋮ & ⋮ & ⋱ & ⋮ \\ {b}_{n , 1} ( m ) & {b}_{n , 2} ( m ) & … & {b}_{n , {K}_{n}} ( m )\end{matrix} ] [ \begin{matrix}{x}_{n , 1} \\ {x}_{n , 2} \\ ⋮ \\ {x}_{n , {K}_{n}}\end{matrix} ] = {B}_{n} {X}_{n} ;$$

and
construct the mixed integer programming model:

$${min}_{A , {B}_{n}} {‖ X - DA - {\sum }_{n = 1}^{N} {B}_{n} {X}_{n} ‖}_{F}^{2} + β {‖ U - QA ‖}_{F}^{2} \\ s . t . : A \geq 0 ,$$

where X represents a load curve read out by a master smart meter of a user, β represents a regular term coefficient, U represents a column vector composed of 1, Q represents a signal grouping matrix, A represents an activation coefficient matrix, N represents a quantity of steady load devices, Xₙ represents a power state matrix, Bₙ represents a state selection matrix, and m represents a length of a time series intercepted for one optimization.

In some embodiments, the first calculation module 300 is further configured to: set the industrial process constraint as:

γ∥RA∥_{F}²; and
restrict a maximum duration for the steady load device and a minimum duration for the steady load device,
wherein the maximum duration W_{n,k} is constrained using a set of linear inequalities:

$${\sum }_{i = t}^{t + {W}_{n , k} - 1} {b}_{n , k} ( i ) \leq {W}_{n , k} - 1 ; and \\ ∀ t ∈ \{ 1 , 2 , … , m - {W}_{n , k} + 1 \} ;$$

and wherein the minimum duration w_{n,k} is constrained using a set of linear inequalities:

$${\sum }_{i = t}^{t + {w}_{n , k} - 1} {b}_{n , k} ( i ) \geq {w}_{n , k} ( {b}_{n , k} ( t ) - {b}_{n , k} ( t - 1 ) ) ; and \\ ∀ t ∈ \{ 2 , 3 , … , m - {w}_{n , k} + 1 \} ,$$

where γ represents a regular term coefficient, and R represents a process restriction matrix.

It should be noted that the above explanation of the embodiments of the mixed integer programming-based load disaggregation method for the industrial facility is also applicable for the mixed integer programming-based load disaggregation apparatus for the industrial facility according to the embodiments, and thus details thereof will be omitted here.

With the mixed integer programming-based load disaggregation apparatus for the industrial facility according to the embodiments of the present disclosure, by obtaining the device asset list of to-be-disaggregated industrial facilities, the industrial devices are categorized into the dynamic load device whose power is continuously adjustable and the steady load device whose power is switched between fixed states. A predetermined scale of device-level power consumption data is used as a training set. An appropriate load curve of the dynamic load device is processed through the digital filtering. The training dataset of the highly fluctuating pulse portion of the load is expanded using the time invariance of the highly fluctuating pulse portion of the load. The mixed integer programming model for disaggregation is constructed using the device information and training data. Model modifiers or constraints are introduced using physical restrictions such as industrial process dependencies of some devices. The programming problem is solved to obtain the disaggregation result. Therefore, the problem of the difficulty of conventional load disaggregation techniques in effectively handling the complex device load identification in industrial scenarios under restrictions of insufficient industrial load data and difficult data collection can be solved. According to the present disclosure, the load characteristics of both the dynamic load device and the steady load device can be taken into consideration simultaneously, in such a manner that the non-intrusive load disaggregation having a high degree of accuracy can be performed in industrial scenarios.

FIG. 4 is a schematic diagram of a structure of an electronic device according to an embodiment of the present disclosure. The electronic device may include a memory 401, a processor 402, and a computer program stored in the memory 401 and executable on the processor 402. The processor 402 is configured to, when executing the computer program, implement the mixed integer programming-based load disaggregation method for the industrial facility according to any of the above embodiments.

Further, the electronic device includes: a communication interface 403 configured to communicate between the memory 401 and the processor 402. The memory 401 stores a computer program executable on the processor 402. The memory 401 may include a high-speed Random Access Memory (RAM), and may also include a non-volatile memory, such as at least one disk memory.

When the memory 401, the processor 402, and the communication interface 403 are implemented independently, the communication interface 403, the memory 401, and the processor 402 may be interconnected and communicate with each other via a bus. The bus may be an Industry Standard Architecture (ISA) bus, a Peripheral Component (PCI) bus, or an Extended Industry Standard Architecture (EISA) bus. The buses may be divided into an address bus, a data bus, a control bus, etc. For the convenience of description, only one thick line is used in FIG. 4, but it does not mean that there is only one bus or one type of bus.

Optionally, in a specific implementation, when the memory 401, the processor 402, and the communication interface 403 are integrated on a single chip for an implementation, the memory 401, the processor 402, and the communication interface 403 may communicate with each other through an internal interface.

The processor 402 may be a Central Processing Unit (CPU), or an Application Specific Integrated Circuit (ASIC), or one or more integrated circuits configured to implement an embodiment of the present disclosure.

A computer-readable storage medium is further provided according to an embodiment of the present disclosure. The computer-readable storage medium stores a computer program. The computer program is configured to, when executed by a processor, implement the mixed integer programming-based load disaggregation method for the industrial facility as described above.

In the description of this specification, descriptions with reference to the terms “an embodiment”, “some embodiments”, “examples”, “specific examples”, or “some examples” etc., mean that specific features, structure, materials or characteristics described in conjunction with the embodiment or example are included in at least one embodiment or example of the present disclosure. In this specification, the schematic representations of the above terms do not necessarily refer to the same embodiment or example. Moreover, the described specific features, structures, materials or characteristics may be combined in any one or more embodiments or examples in a suitable manner. In addition, those skilled in the art can combine the different embodiments or examples and the features of the different embodiments or examples described in this specification without contradicting each other.

In addition, the terms “first” and “second” are only used for descriptive purposes, and cannot be understood as indicating or implying relative importance or implicitly indicating the number of indicated technical features. Therefore, the features defined with “first” and “second” may explicitly or implicitly include at least one of the features. In the description of the present disclosure, “N” means at least two, such as two, three, etc., unless otherwise specifically defined.

Any process or method described in a flowchart or described herein in other ways may be understood to include one or N modules, segments, or portions of codes of executable instructions for achieving specific logical functions or steps in the process. The scope of a preferred embodiment of the present disclosure includes other implementations. A function may be performed not in a sequence shown or discussed, including a substantially simultaneous manner or a reverse sequence based on the function involved, which should be understood by those skilled in the art to which the embodiments of the present disclosure belong.

The logics and/or steps represented in the flowchart or described otherwise herein can be for example considered as a list of ordered executable instructions for implementing logic functions, and can be embodied in any computer-readable medium that is to be used by or used with an instruction execution system, apparatus, or device (such as a computer-based system, a system including a processor, or any other system that can retrieve and execute instructions from an instruction execution system, apparatus, or device). For the present disclosure, a “computer-readable medium” can be any apparatus that can contain, store, communicate, propagate, or transmit a program to be used by or used with an instruction execution system, apparatus, or device. More specific examples of computer-readable mediums include, as a non-exhaustive list: an electrical connector (electronic device) with one or N wirings, a portable computer disk case (magnetic device), a Random Access Memory (RAM), a Read Only Memory (ROM), an Erasable Programmable Read Only Memory (EPROM or flash memory), a fiber optic device, and a portable Compact Disk Read Only Memory (CDROM). In addition, the computer-readable medium may even be paper or other suitable medium on which the program can be printed, as the program can be obtained electronically, e.g., by optically scanning the paper or the other medium, and then editing, interpreting, or otherwise processing the scanning result when necessary, and then stored in a computer memory.

It should be understood that each part of the present disclosure may be realized by hardware, software, firmware, or a combination thereof. In the above embodiments, N steps or methods may be realized by software or firmware stored in the memory and executed by an appropriate instruction execution system. For example, when it is realized by the hardware, likewise in another embodiment, the steps or methods may be realized by one or a combination of the following techniques known in the art: a discrete logic circuit having a logic gate circuit for realizing a logic function of a data signal, an application-specific integrated circuit having an appropriate combination logic gate circuit, a Programmable Gate Array (PGA), a Field Programmable Gate Array (FPGA), etc.

It should be understood by those skilled in the art that all or a part of the steps carried by the method in the above-described embodiments may be completed by relevant hardware instructed by a program. The program may be stored in a computer-readable storage medium. When the program is executed, one or a combination of the steps of the method in the above-described embodiments may be included.

In addition, the functional units in various embodiments of the present disclosure may be integrated into one processing module, or each unit may be standalone physically, or two or more units may be integrated into one module. The above integrated module can be implemented in a form of hardware or in a form of a software functional module. When implemented in the form of the software function module and sold or used as an independent product, the integrated module can also be stored in a computer-readable storage medium.

The storage medium mentioned above may be a read only memory, a magnetic disk or an optical disc, etc. Although the embodiments of the present disclosure have been shown and described above, it can be appreciated that the above embodiments are exemplary only, and should not be construed as limiting the present disclosure. Various changes, modifications, replacements and variants can be made to the above embodiments by those skilled in the art without departing from the scope of the present disclosure.

What is claimed is:

1. A mixed integer programming-based load disaggregation method for an industrial facility, the method comprising:
obtaining a device list of to-be-disaggregated industrial devices and a to-be-disaggregated load curve, and obtaining device-level load curves of individual devices based on the device list and the to-be-disaggregated load curve;
dividing the to-be-disaggregated industrial devices into a dynamic load device and a steady load device based on power consumption characteristics, performing digital filtering on the device-level load curve of the dynamic load device, and obtaining the processed load curve of the dynamic load device by expanding a highly fluctuating pulse portion of a load using time invariance;
constructing a mixed integer programming model based on the processed load curve of the dynamic load device and the load curve of the steady load device, and solving for an optimal value of an optimization variable subsequent to introducing a correction of an industrial process constraint and a device operation restriction into the mixed integer programming model; and
reconstructing, based on an optimization problem model, a disaggregation result for a processed composite signal matrix of the dynamic load device, and reconstructing, based on the optimization problem model, a disaggregation result for the steady load device transformed into a power state sequence.

2. The method according to claim 1, wherein said performing the digital filtering on the device-level load curve of the dynamic load device, and obtaining the processed load curve of the dynamic load device by expanding the highly fluctuating pulse portion of the load using the time invariance comprises:
removing, by using median filtering, a noise spike from the device-level load curve of the dynamic load device, detecting a large-slope portion of the device-level load curve of the dynamic load device to separate the large-slope portion from the device-level load curve of the dynamic load device, and disaggregating the load of each dynamic device into a smooth basic portion and the highly fluctuating pulse portion;
generating column vectors having elements equal to zero in a predetermined time period, connecting the column vectors to a beginning of each to-be-expanded base vector, discarding a sequence of a same length as the column vectors at an end of the to-be-expanded base vector to obtain an expanded pulse lagging by one unit, and obtaining a new base vector by superimposing the expanded pulse on the smooth basic portion; and
obtaining the processed load curve of the dynamic load device based on the new base vector and the highly fluctuating pulse portion.

3. The method according to claim 2, wherein said dividing the to-be-disaggregated industrial devices into the dynamic load device and the steady load device based on the power consumption characteristics comprises:
modeling the steady load device using a combinatorial optimization method:
$${\hat{X}}_{n} ( t ) = {\sum }_{k = 1}^{{K}_{n}} {b}_{n , k} ( t ) {x}_{n , k} , ∀ t ∈ T ; \\ s . t . : {b}_{n , k} ( t ) ∈ \{ 0 , 1 \} , ∀ t ∈ T ; and \\ {\sum }_{k = 1}^{{K}_{n}} {b}_{n , k} ( t ) = 1 , ∀ t ∈ T ,$$
where \hat{X}ₙ(t) represents power of device n at a time point t, t represents a time point, T represents a length of a time series for one optimization, n represents a device serial number, b_{n,k}(t) represents a variable for determining a power state of device n, k represents an integer in [1, Kₙ], and Kₙ represents a quantity of states of device n; and
modeling the dynamic load device using a linear combination of the device-level load curves known for the individual devices:
$${\hat{X}}_{n} = {D}_{n} {A}_{n} ; and \\ s . t . : {A}_{n} \geq 0 ,$$
where \hat{X}ₙ represents a power time series of device n, Dₙ represents a signal matrix of device n, and Aₙ represents an activation coefficient matrix.

4. The method according to claim 3, wherein said constructing the mixed integer programming model based on the processed load curve of the dynamic load device and the load curve of the steady load device comprises:
connecting signal matrices of individual dynamic load devices as D=[D₁, D₂, . . . , Dₙ], and expressing a load model of the steady load device in a form of a matrix:
$${\hat{X}}_{n} ( t ) = [ \begin{matrix}{b}_{n , 1} ( t ) & {b}_{n , 2} ( t ) & … & {b}_{n , {K}_{n}} ( t )\end{matrix} ] [ \begin{matrix}{x}_{n , 1} \\ {x}_{n , 2} \\ ⋮ \\ {x}_{n , {K}_{n}}\end{matrix} ] , ∀ t ∈ T ;$$
summing dimensions of a same base vector in the signal matrices to obtain:
$${\hat{X}}_{n} = [ \begin{matrix}{\hat{X}}_{n} ( 1 ) \\ {\hat{X}}_{n} ( 2 ) \\ ⋮ \\ {\hat{X}}_{n} ( m )\end{matrix} ] = [ \begin{matrix}{b}_{n , 1} ( 1 ) & {b}_{n , 2} ( 2 ) & … & {b}_{n , {K}_{n}} ( 1 ) \\ {b}_{n , 1} ( 2 ) & {b}_{n , 2} ( 2 ) & … & {b}_{n , {K}_{n}} ( 2 ) \\ ⋮ & ⋮ & ⋱ & ⋮ \\ {b}_{n , 1} ( m ) & {b}_{n , 2} ( m ) & … & {b}_{n , {K}_{n}} ( m )\end{matrix} ] [ \begin{matrix}{x}_{n , 1} \\ {x}_{n , 2} \\ ⋮ \\ {x}_{n , {K}_{n}}\end{matrix} ] = {B}_{n} {X}_{n} ;$$
and
constructing the mixed integer programming model:
$${min}_{A , {B}_{n}} {‖ X - DA - {\sum }_{n = 1}^{N} {B}_{n} {X}_{n} ‖}_{F}^{2} + β {‖ U - QA ‖}_{F}^{2} \\ s . t . : A \geq 0 ,$$
where X represents a load curve read out by a master smart meter of a user, β represents a regular term coefficient, U represents a column vector composed of 1, Q represents a signal grouping matrix, A represents an activation coefficient matrix, N represents a quantity of steady load devices, Xₙ represents a power state matrix, Bₙ represents a state selection matrix, and m represents a length of a time series intercepted for one optimization.

5. The method according to claim 1, wherein said introducing the correction of the industrial process constraint and the device operation restriction into the mixed integer programming model comprises:
setting the industrial process constraint as:
γ∥RA∥_{F}²; and
restricting a maximum duration for the steady load device and a minimum duration for the steady load device,
wherein the maximum duration W_{n,k} is constrained using a set of linear inequalities:
$${\sum }_{i = t}^{t + {W}_{n , k} - 1} {b}_{n , k} ( i ) \leq {W}_{n , k} - 1 ; and \\ ∀ t ∈ \{ 1 , 2 , … , m - {W}_{n , k} + 1 \} ;$$
and wherein the minimum duration w_{n,k} is constrained using a set of linear inequalities:
$${\sum }_{i = t}^{t + {w}_{n , k} - 1} {b}_{n , k} ( i ) \geq {w}_{n , k} ( {b}_{n , k} ( t ) - {b}_{n , k} ( t - 1 ) ) ; and \\ ∀ t ∈ \{ 2 , 3 , … , m - {w}_{n , k} + 1 \} ,$$
where γ represents a regular term coefficient, and R represents a process restriction matrix.

6. A mixed integer programming-based load disaggregation apparatus for an industrial facility, the apparatus comprising:
an obtaining module configured to obtain a device list of to-be-disaggregated industrial devices and a to-be-disaggregated load curve, and obtain device-level load curves of individual devices based on the device list and the to-be-disaggregated load curve;
a processing module configured to: divide the to-be-disaggregated industrial devices into a dynamic load device and a steady load device based on power consumption characteristics, perform digital filtering on the device-level load curve of the dynamic load device, and obtain the processed load curve of the dynamic load device by expanding a highly fluctuating pulse portion of a load using time invariance;
a first calculation module configured to construct a mixed integer programming model based on the processed load curve of the dynamic load device and the load curve of the steady load device, and solve for an optimal value of an optimization variable subsequent to introducing a correction of an industrial process constraint and a device operation restriction into the mixed integer programming model; and
a second calculation module configured to reconstruct, based on an optimization problem model, a disaggregation result for a processed composite signal matrix of the dynamic load device, and reconstruct, based on the optimization problem model, a disaggregation result for the steady load device transformed into a power state sequence.

7. The apparatus according to claim 6, wherein the processing module is specifically configured to:
remove, by using median filtering, a noise spike from the device-level load curve of the dynamic load device, detect a large-slope portion of the device-level load curve of the dynamic load device to separate the large-slope portion from the device-level load curve of the dynamic load device, and disaggregate the load of each dynamic device into a smooth basic portion and the highly fluctuating pulse portion;
generate column vectors having elements equal to zero in a predetermined time period, connect the column vectors to a beginning of each to-be-expanded base vector, discard a sequence of a same length as the column vectors at an end of the to-be-expanded base vector to obtain an expanded pulse lagging by one unit, and obtain a new base vector by superimposing the expanded pulse on the smooth basic portion; and
obtain the processed load curve of the dynamic load device based on the new base vector and the highly fluctuating pulse portion.

8. The apparatus according to claim 7, wherein the processing module is configured to:
model the steady load device using a combinatorial optimization method:
$${\hat{X}}_{n} ( t ) = {\sum }_{k = 1}^{{K}_{n}} {b}_{n , k} ( t ) {x}_{n , k} , ∀ t ∈ T ; \\ s . t . : {b}_{n , k} ( t ) ∈ \{ 0 , 1 \} , ∀ t ∈ T ; and \\ {\sum }_{k = 1}^{{K}_{n}} {b}_{n , k} ( t ) = 1 , ∀ t ∈ T ,$$
where \hat{X}ₙ (t) represents power of device n at a time point t, t represents a time point, T represents a length of a time series for one optimization, n represents a device serial number, b_{n,k}(t) represents a variable for determining a power state of device n, k represents an integer in [1, Kₙ], and Kₙ represents a quantity of states of device n; and
model the dynamic load device using a linear combination of the device-level load curves known for the individual devices:
$${\hat{X}}_{n} = {D}_{n} {A}_{n} ; and \\ s . t . : {A}_{n} \geq 0 ,$$
where \hat{X}ₙ represents a power time series of device n, Dₙ represents a signal matrix of device n, and Aₙ represents an activation coefficient matrix.

9. The apparatus according to claim 8, wherein the first calculation module is further configured to:
connect signal matrices of individual dynamic load devices as D=[D₁, D₂, . . . , Dₙ], and express a load model of the steady load device in a form of a matrix:
$${\hat{X}}_{n} ( t ) = [ \begin{matrix}{b}_{n , 1} ( t ) & {b}_{n , 2} ( t ) & … & {b}_{n , {K}_{n}} ( t )\end{matrix} ] [ \begin{matrix}{x}_{n , 1} \\ {x}_{n , 2} \\ ⋮ \\ {x}_{n , {K}_{n}}\end{matrix} ] , ∀ t ∈ T ;$$
sum dimensions of a same base vector in the signal matrices to obtain:
$${\hat{X}}_{n} = [ \begin{matrix}{\hat{X}}_{n} ( 1 ) \\ {\hat{X}}_{n} ( 2 ) \\ ⋮ \\ {\hat{X}}_{n} ( m )\end{matrix} ] = [ \begin{matrix}{b}_{n , 1} ( 1 ) & {b}_{n , 2} ( 1 ) & … & {b}_{n , {K}_{n}} ( 1 ) \\ {b}_{n , 1} ( 2 ) & {b}_{n , 2} ( 2 ) & … & {b}_{n , {K}_{n}} ( 2 ) \\ ⋮ & ⋮ & ⋱ & ⋮ \\ {b}_{n , 1} ( m ) & {b}_{n , 2} ( m ) & … & {b}_{n , {K}_{n}} ( m )\end{matrix} ] [ \begin{matrix}{x}_{n , 1} \\ {x}_{n , 2} \\ ⋮ \\ {x}_{n , {K}_{n}}\end{matrix} ] = {B}_{n} {X}_{n} ; and$$
construct the mixed integer programming model:
$${min}_{A , {B}_{n}} {‖ X - DA - {\sum }_{n = 1}^{N} {B}_{n} {X}_{n} ‖}_{F}^{2} + β {‖ U - QA ‖}_{F}^{2} \\ s . t . : A \geq 0 ,$$
where X represents a load curve read out by a master smart meter of a user, β represents a regular term coefficient, U represents a column vector composed of 1, Q represents a signal grouping matrix, A represents an activation coefficient matrix, N represents a quantity of steady load devices, Xₙ represents a power state matrix, Bₙ represents a state selection matrix, and m represents a length of a time series intercepted for one optimization.

10. The apparatus according to claim 6, wherein the first calculation module is configured to:
set the industrial process constraint as:
γ∥RA∥_{F}²; and
restrict a maximum duration for the steady load device and a minimum duration for the steady load device,
wherein the maximum duration W_{n,k} is constrained using a set of linear inequalities:
$${\sum }_{i = t}^{t + {W}_{n , k} - 1} {b}_{n , k} ( i ) \leq {W}_{n , k} - 1 ; and \\ ∀ t ∈ \{ 1 , 2 , … , m - {W}_{n , k} + 1 \} ;$$
and wherein the minimum duration w_{n,k} is constrained using a set of linear inequalities:
$${\sum }_{i = t}^{t + {w}_{n , k} - 1} {b}_{n , k} ( i ) \geq {w}_{n , k} ( {b}_{n , k} ( t ) - {b}_{n , k} ( t - 1 ) ) ; and \\ ∀ t ∈ \{ 2 , 3 , … , m - {w}_{n , k} + 1 \} ,$$
where γ represents a regular term coefficient, and R represents a process restriction matrix.

11. An electronic device, comprising:
a memory;
a processor; and
a computer program stored in the memory and executable on the processor,
wherein the processor is configured to, when executing the computer program, implement the method according to claim 1.

12. The electronic device according to claim 11, wherein said performing the digital filtering on the device-level load curve of the dynamic load device, and obtaining the processed load curve of the dynamic load device by expanding the highly fluctuating pulse portion of the load using the time invariance comprises:
removing, by using median filtering, a noise spike from the device-level load curve of the dynamic load device, detecting a large-slope portion of the device-level load curve of the dynamic load device to separate the large-slope portion from the device-level load curve of the dynamic load device, and disaggregating the load of each dynamic device into a smooth basic portion and the highly fluctuating pulse portion;
generating column vectors having elements equal to zero in a predetermined time period, connecting the column vectors to a beginning of each to-be-expanded base vector, discarding a sequence of a same length as the column vectors at an end of the to-be-expanded base vector to obtain an expanded pulse lagging by one unit, and obtaining a new base vector by superimposing the expanded pulse on the smooth basic portion; and
obtaining the processed load curve of the dynamic load device based on the new base vector and the highly fluctuating pulse portion.

13. The electronic device according to claim 12, wherein said dividing the to-be-disaggregated industrial devices into the dynamic load device and the steady load device based on the power consumption characteristics comprises:
modeling the steady load device using a combinatorial optimization method:
$${\hat{X}}_{n} ( t ) = {\sum }_{k = 1}^{{K}_{n}} {b}_{n , k} ( t ) {x}_{n , k} , ∀ t ∈ T ; \\ s . t . : {b}_{n , k} ( t ) ∈ \{ 0 , 1 \} , ∀ t ∈ T ; and \\ {\sum }_{k = 1}^{{K}_{n}} {b}_{n , k} ( t ) = 1 , ∀ t ∈ T ,$$
where \hat{X}ₙ(t) represents power of device n at a time point t, t represents a time point, T represents a length of a time series for one optimization, n represents a device serial number, b_{n,k}(t) represents a variable for determining a power state of device n, k represents an integer in [1, Kₙ], and Kₙ represents a quantity of states of device n; and
modeling the dynamic load device using a linear combination of the device-level load curves known for the individual devices:
$${\hat{X}}_{n} = {D}_{n} {A}_{n} ; and \\ s . t . : {A}_{n} \geq 0 ,$$
where \hat{X}ₙ represents a power time series of device n, Dₙ represents a signal matrix of device n, and Aₙ represents an activation coefficient matrix.

14. The electronic device according to claim 13, wherein said constructing the mixed integer programming model based on the processed load curve of the dynamic load device and the load curve of the steady load device comprises:
connecting signal matrices of individual dynamic load devices as D=[D₁, D₂, . . . , Dₙ], and expressing a load model of the steady load device in a form of a matrix:
$${\hat{X}}_{n} ( t ) = [ \begin{matrix}{b}_{n , 1} ( t ) & {b}_{n , 2} ( t ) & … & {b}_{n , {K}_{n}} ( t )\end{matrix} ] [ \begin{matrix}{x}_{n , 1} \\ {x}_{n , 2} \\ ⋮ \\ {x}_{n , {K}_{n}}\end{matrix} ] , ∀ t ∈ T ;$$
summing dimensions of a same base vector in the signal matrices to obtain:
$${\hat{X}}_{n} = [ \begin{matrix}{\hat{X}}_{n} ( 1 ) \\ {\hat{X}}_{n} ( 2 ) \\ ⋮ \\ {\hat{X}}_{n} ( m )\end{matrix} ] = [ \begin{matrix}{b}_{n , 1} ( 1 ) & {b}_{n , 2} ( 1 ) & … & {b}_{n , {K}_{n}} ( 1 ) \\ {b}_{n , 1} ( 2 ) & {b}_{n , 2} ( 2 ) & … & {b}_{n , {K}_{n}} ( 2 ) \\ ⋮ & ⋮ & ⋱ & ⋮ \\ {b}_{n , 1} ( m ) & {b}_{n , 2} ( m ) & … & {b}_{n , {K}_{n}} ( m )\end{matrix} ] [ \begin{matrix}{x}_{n , 1} \\ {x}_{n , 2} \\ ⋮ \\ {x}_{n , {K}_{n}}\end{matrix} ] = {B}_{n} {X}_{n} ;$$
and
constructing the mixed integer programming model:
$${min}_{A , {B}_{n}} {‖ X - DA - {\sum }_{n = 1}^{N} {B}_{n} {X}_{n} ‖}_{F}^{2} + β {‖ U - QA ‖}_{F}^{2} \\ s . t . : A \geq 0 ,$$
where X represents a load curve read out by a master smart meter of a user, β represents a regular term coefficient, U represents a column vector composed of 1, Q represents a signal grouping matrix, A represents an activation coefficient matrix, N represents a quantity of steady load devices, Xₙ represents a power state matrix, Bₙ represents a state selection matrix, and m represents a length of a time series intercepted for one optimization.

15. The electronic device according to claim 11, wherein said introducing the correction of the industrial process constraint and the device operation restriction into the mixed integer programming model comprises:
setting the industrial process constraint as:
γ∥RA∥_{F}²; and
restricting a maximum duration for the steady load device and a minimum duration for the steady load device,
wherein the maximum duration W_{n,k} is constrained using a set of linear inequalities:
$${\sum }_{i = t}^{t + {W}_{n , k} - 1} {b}_{n , k} ( i ) \leq {W}_{n , k} - 1 ; and \\ ∀ t ∈ \{ 1 , 2 , … , m - {W}_{n , k} + 1 \} ;$$
and wherein the minimum duration w_{n,k} is constrained using a set of linear inequalities:
$${\sum }_{i = t}^{t + {w}_{n , k} - 1} {b}_{n , k} ( i ) \geq {w}_{n , k} ( {b}_{n , k} ( t ) - {b}_{n , k} ( t - 1 ) ) ; and \\ ∀ t ∈ \{ 2 , 3 , … , m - {w}_{n , k} + 1 \} ,$$
where γ represents a regular term coefficient, and R represents a process restriction matrix.

16. A computer-readable storage medium, having a computer program stored thereon, wherein the computer program is configured to, when executed by a processor, implement the method according to claim 1.

17. The computer-readable storage medium according to claim 16, wherein said performing the digital filtering on the device-level load curve of the dynamic load device, and obtaining the processed load curve of the dynamic load device by expanding the highly fluctuating pulse portion of the load using the time invariance comprises:
removing, by using median filtering, a noise spike from the device-level load curve of the dynamic load device, detecting a large-slope portion of the device-level load curve of the dynamic load device to separate the large-slope portion from the device-level load curve of the dynamic load device, and disaggregating the load of each dynamic device into a smooth basic portion and the highly fluctuating pulse portion;
generating column vectors having elements equal to zero in a predetermined time period, connecting the column vectors to a beginning of each to-be-expanded base vector, discarding a sequence of a same length as the column vectors at an end of the to-be-expanded base vector to obtain an expanded pulse lagging by one unit, and obtaining a new base vector by superimposing the expanded pulse on the smooth basic portion; and
obtaining the processed load curve of the dynamic load device based on the new base vector and the highly fluctuating pulse portion.

18. The computer-readable storage medium according to claim 17, wherein said dividing the to-be-disaggregated industrial devices into the dynamic load device and the steady load device based on the power consumption characteristics comprises:
modeling the steady load device using a combinatorial optimization method:
$${\hat{X}}_{n} ( t ) = {\sum }_{k = 1}^{{K}_{n}} {b}_{n , k} ( t ) {x}_{n , k} , ∀ t ∈ T ; \\ s . t . : {b}_{n , k} ( t ) ∈ \{ 0 , 1 \} , ∀ t ∈ T ; and \\ {\sum }_{k = 1}^{{K}_{n}} {b}_{n , k} ( t ) = 1 , ∀ t ∈ T ,$$
where \hat{X}ₙ(t) represents power of device n at a time point t, t represents a time point, T represents a length of a time series for one optimization, n represents a device serial number, b_{n,k} (t) represents a variable for determining a power state of device n, k represents an integer in [1, Kₙ], and Kₙ represents a quantity of states of device n; and
modeling the dynamic load device using a linear combination of the device-level load curves known for the individual devices:
$${\hat{X}}_{n} = {D}_{n} {A}_{n} ; and \\ s . t . : {A}_{n} \geq 0 ,$$
where \hat{X}ₙ represents a power time series of device n, Dₙ represents a signal matrix of device n, and Aₙ represents an activation coefficient matrix.

19. The computer-readable storage medium according to claim 18, wherein said constructing the mixed integer programming model based on the processed load curve of the dynamic load device and the load curve of the steady load device comprises:
connecting signal matrices of individual dynamic load devices as D=[D₁, D₂, . . . , Dₙ], and expressing a load model of the steady load device in a form of a matrix:
$${\hat{X}}_{n} ( t ) = [ \begin{matrix}{b}_{n , 1} ( t ) & {b}_{n , 2} ( t ) & … & {b}_{n , {K}_{n}} ( t )\end{matrix} ] [ \begin{matrix}{x}_{n , 1} \\ {x}_{n , 2} \\ ⋮ \\ {x}_{n , {K}_{n}}\end{matrix} ] , ∀ t ∈ T ;$$
summing dimensions of a same base vector in the signal matrices to obtain:
$${\hat{X}}_{n} = [ \begin{matrix}{\hat{X}}_{n} ( 1 ) \\ {\hat{X}}_{n} ( 2 ) \\ ⋮ \\ {\hat{X}}_{n} ( m )\end{matrix} ] = [ \begin{matrix}{b}_{n , 1} ( 1 ) & {b}_{n , 2} ( 1 ) & ⋯ & {b}_{n , {K}_{n}} ( 1 ) \\ {b}_{n , 1} ( 2 ) & {b}_{n , 2} ( 2 ) & ⋯ & {b}_{n , {K}_{n}} ( 2 ) \\ ⋮ & ⋮ & ⋱ & ⋮ \\ {b}_{n , 1} ( m ) & {b}_{n , 2} ( m ) & ⋯ & {b}_{n , {K}_{n}} ( m )\end{matrix} ] [ \begin{matrix}{x}_{n , 1} \\ {x}_{n , 2} \\ ⋮ \\ {x}_{n , {K}_{n}}\end{matrix} ] = {B}_{n} {X}_{n} ; and$$
constructing the mixed integer programming model:
$${min}_{A , {B}_{n}} {‖ X - D A - {\sum }_{n = 1}^{N} {B}_{n} {X}_{n} ‖}_{F}^{2} + β {‖ U - QA ‖}_{F}^{2}$$
$$s . t . :$$
$$A \geq 0 ,$$
where X represents a load curve read out by a master smart meter of a user, β represents a regular term coefficient, U represents a column vector composed of 1, Q represents a signal grouping matrix, A represents an activation coefficient matrix, N represents a quantity of steady load devices, Xₙ represents a power state matrix, Bₙ represents a state selection matrix, and m represents a length of a time series intercepted for one optimization.

20. The computer-readable storage medium according to claim 16, wherein said introducing the correction of the industrial process constraint and the device operation restriction into the mixed integer programming model comprises:
setting the industrial process constraint as:
γ∥RA∥_{F}²; and
restricting a maximum duration for the steady load device and a minimum duration for the steady load device,
wherein the maximum duration W_{n,k} is constrained using a set of linear inequalities:
$${\sum }_{i = t}^{t + {W}_{n , k} - 1} {b}_{n , k} ( i ) \leq {W}_{n , k} - 1 ;$$
$$and$$
$$∀ t ∈ \{ 1 , 2 , … , m - {W}_{n , k} + 1 \} ;$$
and wherein the minimum duration w_{n,k} is constrained using a set of linear inequalities:
$${\sum }_{i = t}^{t + {w}_{n , k} - 1} {b}_{n , k} ( i ) \geq {w}_{n , k} ( {b}_{n , k} ( t ) - {b}_{n , k} ( t - 1 ) ) ;$$
$$and$$
$$∀ t ∈ \{ 2 , 3 , … , m - {w}_{n , k} + 1 \} ,$$
where γ represents a regular term coefficient, and R represents a process restriction matrix.
